(19) United States
(12) Patent Application Publication
(10) Pub. No.: US 2024/0429266 A1
(43) Pub. Date: Dec. 26, 2024

(54) SEMICONDUCTOR CIRCUIT, MEMORY SYSTEM, AND INFORMATION PROCESSING DEVICE

(71) Applicant: Kioxia Corporation, Tokyo (JP)

(72) Inventor: Takashi Toi, Yokohama Kanagawa (JP)

(73) Assignee: Kioxia Corporation, Tokyo (JP)

(21) Appl. No.: 18/743,825

(22) Filed: Jun. 14, 2024

(30) Foreign Application Priority Data
Jun. 22, 2023 (JP) 2023-102628

(51) Int. Cl. H10B 41/00

(52) U.S. Cl. CPC H01L 28/10; H10B 41/00

(57) ABSTRACT

According to one embodiment, a semiconductor circuit includes a semiconductor substrate, a first T-coil including a first inductive element and a second inductive element which are coupled in series, and a second T-coil including a third inductive element and a fourth inductive element which are coupled in series. A part of the first T-coil is provided at a first position. A part of the second T-coil is provided at a second position to overlap with the part of the first T-coil in the vertical direction. A first distance from the semiconductor substrate to the first position is different from a second distance from the semiconductor substrate to the second position. The first T-coil is configured to receive a first signal having a first polarity of a differential signal. The second T-coil is configured to receive a second signal having a second polarity different from the first polarity.

### CROSS-REFERENCE TO RELATED APPLICATIONS

This application is based upon and claims the benefit of priority from Japanese Patent Application No. 2023-102628, filed Jun. 22, 2023, the entire contents of which are incorporated herein by reference.

### FIELD

Embodiments described herein relate generally to a semiconductor circuit, a memory system, and an information processing device.

### BACKGROUND

In order to improve the quality of signal transmission and reception, semiconductor circuits having a variety of configurations using a variety of circuit elements have been researched and developed. In these semiconductor circuits, an on-chip coil provided above a semiconductor substrate is known.

### BRIEF DESCRIPTION OF THE DRAWINGS

FIG. 1 is a block diagram showing an overall configuration of a system including a semiconductor circuit according to a first embodiment.

FIG. 2 is a schematic diagram showing an example of a configuration of a receiver including a receiving circuit according to the first embodiment.

FIG. 3 is a circuit diagram showing an example of a configuration of the receiving circuit according to the first embodiment.

FIG. 4 is a plan view illustrating an example of a layout of a T-coil according to the first embodiment.

FIG. 5 is a plan view illustrating another example of the layout of the T-coil according to the first embodiment.

FIG. 6 is a plan view illustrating a layout of a T-coil pair according to the first embodiment.

FIG. 7 is a cross-sectional view illustrating the layout of the T-coil pair according to the first embodiment.

FIG. 8 is a plan view illustrating directions of signal currents flowing through the T-coil pair according to the first embodiment.

FIG. 9 is a plan view illustrating an example of a layout of a T-coil according to a second embodiment.

FIG. 10 is a plan view illustrating another example of the layout of the T-coil according to the second embodiment.

FIG. 11 is a plan view illustrating a layout of a T-coil pair according to the second embodiment.

FIG. 12 is a cross-sectional view illustrating the layout of the T-coil pair according to the second embodiment.

FIG. 13 is a plan view illustrating directions of signal currents flowing through the T-coil pair according to the second embodiment.

FIG. 14 is a circuit diagram showing an example of a configuration of a termination circuit and a receiving circuit according to a first modification.

FIG. 15 is a schematic diagram showing an example of a configuration of a transmitter according to a second modification.

FIG. 16 is a circuit diagram showing an example of a configuration of a termination circuit and a transmission circuit according to the second modification.

### DETAILED DESCRIPTION

In general, according to one embodiment, a semiconductor circuit includes a semiconductor substrate, a first T-coil provided apart from the semiconductor substrate and including a first inductive element and a second inductive element which are coupled in series, and a second T-coil provided apart from the semiconductor substrate and including a third inductive element and a fourth inductive element which are coupled in series. A part of the first T-coil is provided at a first position in a vertical direction from a surface of the semiconductor substrate. A part of the second T-coil is provided at a second position in the vertical direction from the surface to overlap with the part of the first T-coil in the vertical direction. In the vertical direction, a first distance from the semiconductor substrate to the first position is different from a second distance from the semiconductor substrate to the second position. The first T-coil is configured to receive a first signal having a first polarity of a differential signal. The second T-coil is configured to receive a second signal having a second polarity different from the first polarity of the differential signal.

Embodiments will be described below with reference to the drawings. In the description, components having substantially the same function and configuration are denoted by the same reference symbol. The following embodiments exemplify technical concepts. The embodiments do not specify the material, shape, configuration, placement or the like of the components. A variety of modifications can be made to the embodiments.

### <1> First Embodiment

A semiconductor circuit according to a first embodiment will be described. In the first embodiment, a receiving circuit will be described as an example of the semiconductor circuit according to the first embodiment. Below is a description of an example of a system including a receiving circuit.

### <1-1> Configuration

### <1-1-1> Overall Configuration of Information Processing System

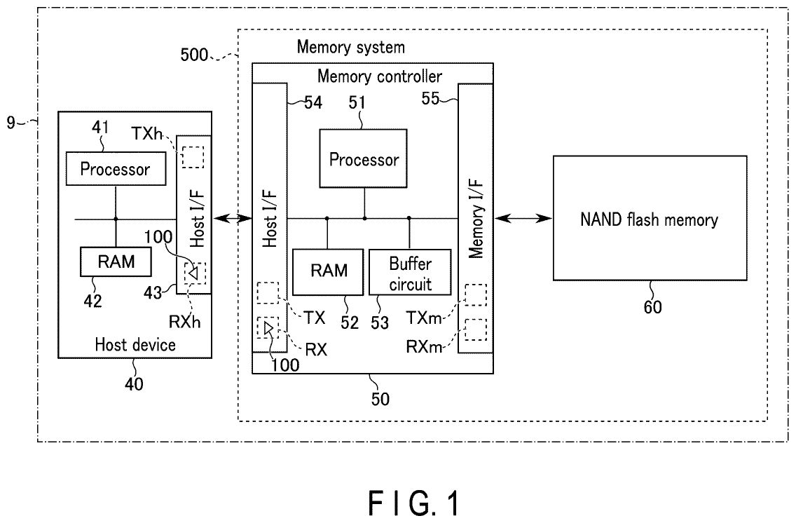

FIG. 1 is a block diagram showing an overall configuration of a system including a circuit according to the first embodiment.

As shown in FIG. 1, an information processing system 9 includes a host device 40 and a memory system 500. The memory system 500 performs a write operation, a read operation, and an erase operation in response to a request from the host device 40. An internal configuration of the memory system 500 will be described later.

The host device 40 includes a processor 41, a RAM 42, and an interface circuit 43. The host device 40 is an example of an information processing device.

The processor (also referred to as a host processor hereinafter) 41 controls a variety of processes and operations in the host device 40.

The host processor 41 is capable of issuing (generating and transferring) a command (referred to as a host command hereinafter) to request (order, instruct) the memory system 500 to perform a variety of processes and operations. The host processor 41 is capable of generating data corresponding to the host command. The generated data includes, information (e.g. address) for use in the processes and operations in the memory system 500, parameters, and data to be written to the memory system 500.

The RAM 42 functions as a work area (work memory) for a variety of data processes to be performed by the host processor 41. The RAM 42 temporarily stores programs (an example of software) and data (results of calculation, data currently being calculated, and parameters) for use in a variety of processes to be performed by the host processor 41.

The interface circuit (also referred to as a host interface (host I/F) circuit) 43 communicates with the memory system 500 based on an interface standard and/or a communication protocol. The interface circuit 43 includes a transmitter TXh for data transmission and a receiver RXh for data reception in a physical layer (PHY layer).

The host command to the memory system 500 is based on the interface standard of the interface circuit 43. Examples of an interface standard (or a communication protocol) for use in the interface circuit 43 are an SAS standard, an SATA standard, a PCI Express™ standard (hereinafter referred to as a PCIe™ standard), an NVM Express™ standard (hereinafter referred to as an NVMe™ standard), a universal flash storage (UFS) standard, and the like. Note that an interface standard conforming to one of those standards or another interface standard may be used for the interface circuit 43.

The host device 40 may further include a storage device (not shown) such as a hard disk drive (HDD) in addition to the foregoing components.

Examples of the host device 40 or the information processing system 9 are a personal computer, a smartphone, a feature phone, a mobile terminal (e.g. a tablet device), a game console, an in-car terminal, a router, a base station, and the like.

### <1-1-2> Configuration of Memory System

The memory system 500 includes a memory controller 50 and a NAND flash memory 60.

In response to a request from the host device 40, the memory controller 50 instructs the NAND flash memory 60 to perform a variety of processes and operations, such as a write operation, a read operation, and an erase operation.

The memory controller 50 includes a processor 51, a RAM 52, a buffer circuit 53, and interface circuits 54 and 55.

The processor 51 is capable of instructing the NAND flash memory 60 to perform a variety of processes or operations. For example, the processor 51 is capable of generating a command (also referred to as a controller command hereinafter) to instruct the NAND flash memory 60.

The RAM 52 functions as a work area for a variety of processes and operations of the processor 51 in the memory controller 50. The RAM 52 temporarily stores programs and data (results of calculation, data currently being calculated, and parameters) for use in a variety of processes to be performed by the processor 51. Note that the RAM 52 may be a memory area provided in the processor 51.

The buffer circuit 53 temporarily stores data to be transferred between the memory controller 50 and the host device 40 and data to be transferred between the memory controller 50 and the NAND flash memory 60.

The interface circuit (also referred to as a host interface (host I/F) circuit) 54 transfers data between the host device 40 and the memory controller 50 based on an interface standard. The interface standard (and communication protocol) of the interface circuit 54 is the same as (or conforms to) the interface standard of the interface circuit 43 of the host device 40. For example, the interface circuit 54 performs serial transmission communication (serial communication) with the interface circuit 43.

The interface circuit (also referred to as a memory interface (memory I/F) circuit) 55 performs communication (e.g. data transfer) between the memory controller 50 and the NAND flash memory 60 based on the NAND interface standard. The interface circuit 55 performs parallel transmission communication (parallel communication) with the NAND flash memory 60, for example. The interface circuit 55 includes a transmitter TXm and a receiver RXm in a physical layer (PHY layer).

If the memory controller 50 instructs the NAND flash memory 60 to perform an operation, it sends a data group (also referred to as a memory command set hereinafter) including a command and an address to the NAND flash memory 60. Note that when the memory controller 50 instructs the NAND flash memory 60 to write data, the memory command set further includes the write data.

Note that the memory controller 50 may include another configuration, such as an error checking and correcting (ECC) circuit (not shown) that checks and corrects an error in data, in addition to the foregoing configuration.

The NAND flash memory 60 is a nonvolatile semiconductor memory device. The NAND flash memory 60 is capable of storing data substantially nonvolatilely. The NAND flash memory 60 writes data received from the memory controller 50 into a memory cell array (not shown). The NAND flash memory 60 reads data, which is requested from the memory controller 50, from the memory cell array. Hereinafter, the NAND flash memory 60 will also be referred to as simply a flash memory 60.

The flash memory 60 communicates with the memory controller 50. Communications between the flash memory 60 and the memory controller 50 are supported by the NAND interface standard.

The memory system 500 is, for example, a solid state drive (SSD), a universal flash storage (UFS) device, a memory card, and a universal serial bus (USB) memory. Note that the flash memory 60 may be replaced by another nonvolatile or volatile memory device in the memory system 500.

In the memory system 500, the interface circuit 54 of the memory controller 50 includes a transmitter TX and a receiver RX in a physical layer (PHY layer).

For communication (signal transmission) between the host device 40 and the memory system 500, the transmitter TX of interface circuit 54 transmits various signals (e.g. data) to the receiver RXh of the interface circuit 43. For communication between the host device 40 and the memory system 500, the receiver RX of the interface circuit 54 receives various signals from the transmitter TXh of the interface circuit 43. For example, in the memory system 500, the memory controller 50 is capable of performing a variety of processes on data received by the receiver RX.

For example, the transmitter TX and the receiver RX are used for relatively high-speed data transfer of 10 Gbps or higher (e.g. data transfer of 100 Gbps level).

The semiconductor circuit according to the first embodiment is, for example, a receiving circuit 100. The receiving circuit 100 of the first embodiment is provided in the receiver RX of the memory controller 50.

Note that the receiving circuit 100 of the first embodiment may be provided in the receiver RXh of the interface circuit 43 of the host device 40.

### <1-1-3> Configuration of Receiver

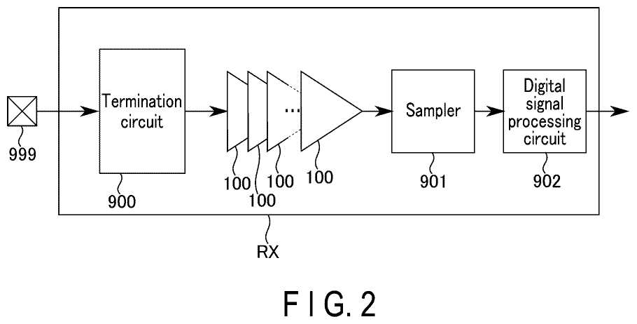

FIG. 2 is a schematic diagram showing an example of a configuration of a receiver including the receiving circuit of the first embodiment.

As shown in FIG. 2, a receiver RX includes a termination circuit 900, a plurality of receiving circuits 100, a sampler 901, and a digital signal processing circuit 902.

The termination circuit 900 is coupled to a receiving terminal (receiving node) 999 of the memory controller 50. The termination circuit 900 includes a resistive element, a capacitance element, a current source, and/or a voltage source, etc. The termination circuit 900 ensures impedance matching of a signal line on the input side of the receiver RX. The termination circuit 900 thus suppresses reflection caused on the signal line of the input side of the receiver RX.

The plurality of receiving circuits 100 are coupled to the termination circuit 900. The plurality of receiving circuits 100 are coupled in series between the termination circuit 900 and the sampler 901.

The receiving circuit 100 in the first stage of the plurality of receiving circuits 100 receives via the termination circuit 900 a signal that is supplied to the receiving terminal 999. The receiving circuit 100 in the final stage of the plurality of receiving circuits 100 receives a signal and supplies it to the sampler 901. Each of the receiving circuits 100 is capable of amplifying the received signal. Upon receiving a differential signal, each of the receiving circuits 100 processes the differential signal and outputs the processed differential signal.

The sampler 901 samples a signal received from the receiving circuit 100 in synchronization with a clock. The sampler 901 supplies the sampled signal (hereinafter referred to as a sampling signal) to the digital signal processing circuit 902.

The digital signal processing circuit 902 processes the sampling signal digitally. For example, the digital signal processing circuit 902 preforms analog to digital conversion for the sampling signal. Then, the digital signal processing circuit 902 supplies the digital signal to a circuit in a subsequent stage.

### <1-1-4> Configuration of Receiving Circuit

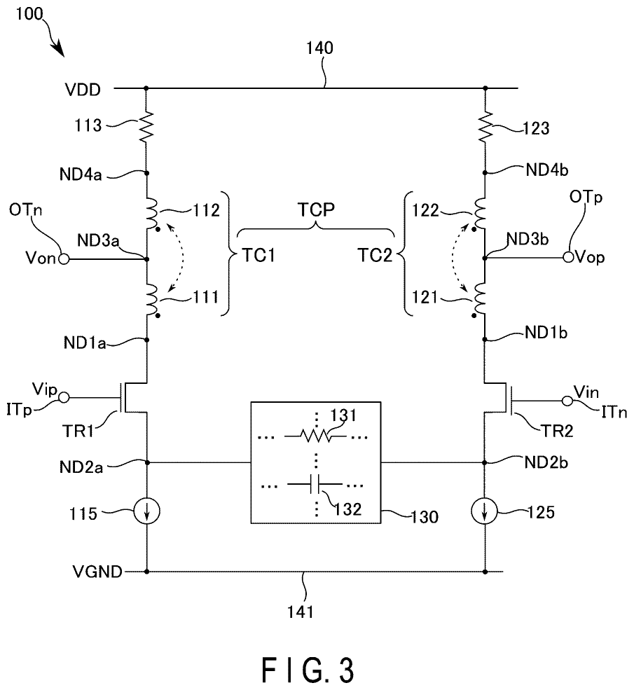

FIG. 3 is a circuit diagram showing an example of a configuration of the receiving circuit of the first embodiment.

As shown in FIG. 3, the receiving circuit 100 according to the first embodiment includes two input terminals ITp and ITn, two output terminals OTp and OTn, a plurality of transistors TR1 and TR2, a plurality of inductive elements 111, 112, 121, and 122, a plurality of resistive elements 113 and 123, a plurality of current sources 115 and 125, an RC network circuit 130, and a plurality of power supply lines 140 and 141.

The receiving circuit 100 according to the first embodiment is a differential input/output receiving circuit. The input terminal ITp is configured to receive a positive polarity signal Vip. The input terminal ITn is configured to receive a negative polarity signal Vin. The output terminal OTp is configured to output a positive polarity signal Vop. The output terminal OTn is configured to output a negative polarity signal Von.

Each of the transistors TR1 and TR2 functions as input unit of signal in the receiving circuit 100. The transistors TR1 and TR2 receive complementary signals (signal voltages, input signals, input voltages) Vip and Vin. Thus, the differential signals Vip and Vin are input to the receiving circuit 100. Each of the transistors TR1 and TR2 is field-effect transistor such as MOS transistor.

One end of the current path of the transistor TR1 is electrically coupled to a node ND1a. The other end of the current path of the transistor TR1 is electrically coupled to a node ND2a. A gate of the transistor TR1 is electrically coupled to the input terminal ITp in the positive polarity side of the receiving circuit 100. The gate of the transistor TR1 receives the positive polarity signal Vip from the preceding-stage termination circuit 900 or the receiving circuit 100.

One end of the current path of the transistor TR2 is electrically coupled to a node ND1b. The other end of the current path of the transistor TR2 is electrically coupled to a node ND2b. A gate of the transistor TR2 is electrically coupled to the input terminal ITn in the negative polarity side of the receiving circuit 100. The gate of the transistor TR2 receives the negative polarity signal Vin from the preceding termination circuit 900 or the receiving circuit 100. The signals Vin and Vip are complementary to each other.

An input node of the current source 115 is electrically coupled to the node ND2a. An output node of the current source 115 is electrically coupled to the power supply line 141 on the low potential side of the receiving circuit 100. A ground voltage VGND is applied to the power supply line 141. Hereinafter, the power supply line 141 will be referred to as a ground line 141. The ground voltage VGND is a reference potential during the operation of the receiving circuit 100.

An input node of the current source 125 is electrically coupled to the node ND2b. An output node of the current source 125 is electrically coupled to the ground line 141.

The RC network circuit 130 is electrically coupled between the node ND2a and the node ND2b. The RC network circuit 130 includes a plurality of resistive elements 131 and a plurality of capacitive elements 132. The RC network circuit 130 has a network in which the resistive elements 131 and capacitive elements 132 are electrically coupled in series and/or in parallel.

Each of the inductive elements 111, 112, 121, and 122 is, for example, an on-chip coil.

One end of the inductive element 111 is electrically coupled to the node ND1a. The other end of the inductive element 111 is electrically coupled to a node ND3a. The polarity of mutual induction of the inductive element 111 is toward the node ND1a of the inductive element 111 (toward one end of the inductive element 111).

One end of the inductive element 112 is electrically coupled to the node ND3a. The other end of the inductive element 112 is electrically coupled to a node ND4a. The polarity of mutual induction of the inductive element 112 is toward the node ND3a of the inductive element 112 (toward one end of the inductive element 112).

One end of the inductive element 121 is electrically coupled to the node ND1b. The other end of the inductive element 121 is electrically coupled to a node ND3b. The polarity of mutual induction of the inductive element 121 is toward the node ND1b of the inductive element 121 (toward one end of the inductive element 121).

One end of the inductive element 122 is electrically coupled to the node ND3b. The other end of the inductive element 122 is electrically coupled to a node ND4b. The polarity of mutual induction of the inductive element 122 is toward the node ND3b of the inductive element 122 (toward one end of the inductive element 122).

One end of the resistive element 113 is electrically coupled to the node ND4a. The other end of the resistive element 113 is electrically coupled to the power supply line 140 on the high potential side of the receiving circuit 100. A power supply voltage VDD is applied to the power supply line 140.

One end of the resistive element 123 is electrically coupled to the node ND4b. The other end of the resistive element 123 is electrically coupled to the power supply line 140.

The output terminal OTp in the positive polarity side of the receiving circuit 100 is electrically coupled to the node ND3b between the other end of the inductive element 121 and one end of the inductive element 122. The output terminal OTn in the negative polarity side of the receiving circuit 100 is electrically coupled to the node ND3a between the other end of the inductive element 111 and one end of the inductive element 112. The receiving circuit 100 outputs a positive polarity signal (signal voltage, output signal, output voltage) Vop from the output terminal OTp. The receiving circuit 100 outputs a negative polarity signal Von from the output terminal OTn. The signals Vop and Von are complementary to each other. Thus, the differential signals Vop and Von are transmitted from the receiving circuit 100 to the subsequent receiving circuit 100 or the sampler 901.

A configuration in which two inductive elements, such as the inductive elements 111 and 112, are coupled in series is also referred to as a T-coil. Hereinafter, the inductive elements 111 and 112 will be referred to as a T-coil TC1, and the inductive elements 121 and 122 will be referred to as a T-coil TC2. In addition, a set of the T-coil TC1 and T-coil TC2 will be referred to as a T-coil pair TCP.

### <1-1-5> Layout of T-Coil Pair

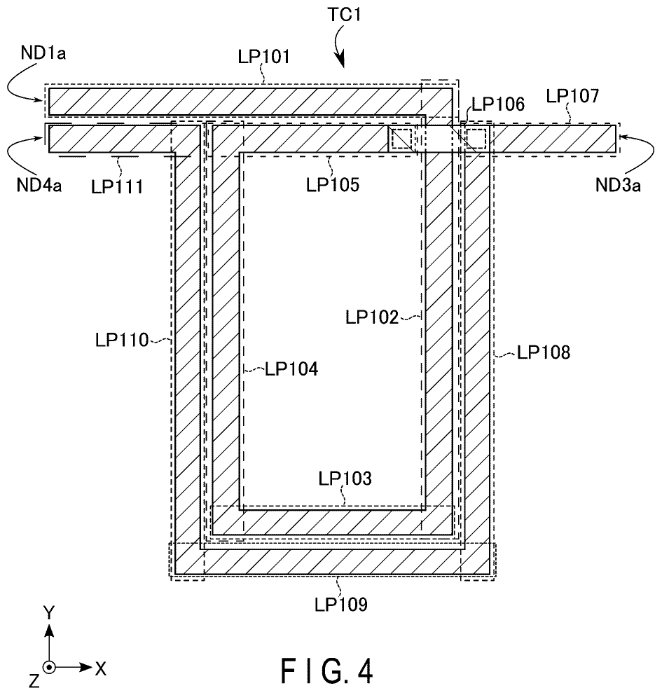

The layout of the T-coil pair according to the first embodiment will be described below with reference to FIGS. 4 to 7. First, a single T-coil TC1 will be described, then a single T-coil TC2 will be described, and finally, a T-coil pair TCP, that is, a combination of the T-coils TC1 and TC2 will be described.

In the drawings referred to in the present specification, a plane defined by the X and Y directions corresponds to a plane parallel to a surface of a semiconductor substrate. The Z direction corresponds to the vertical direction with respect to the surface of the semiconductor substrate. In addition, the horizontal direction in the drawings is defined as the X direction, the direction from the left side of the drawings toward the right side thereof is defined as a positive X direction, and the direction from the right side of the drawings toward the left side thereof is defined as a negative X direction. The vertical direction in the drawings is defined as the Y direction, the direction from the lower side of the drawings toward the upper side thereof is defined as a positive Y direction, and the direction from the upper side of the drawings toward the lower side thereof is defined as a negative Y direction.

FIG. 4 is a plan view illustrating an example of the layout of the T-coil according to the first embodiment. As shown in FIG. 4, the T-coil TC1 is, for example, a two-turn planar coil having a square annular shape. The square annular shape may also be called a square shape, for example. The T-coil TC1 includes interconnects LP101 to LP111. The interconnects LP101 to LP105 and LP107 to LP111 are provided in a first interconnect layer above the semiconductor substrate. The interconnect LP106 is provided in a second interconnect layer that is located above the first interconnect layer. That is, the first interconnect layer is different from the second interconnect layer. The interconnects LP101 to LP106 correspond to the inductive element 111. The interconnects LP108 to LP111 correspond to the inductive element 112. The interconnects LP105 and LP106 may be considered to correspond to the inductive element 112 rather than the inductive element 111.

The interconnect LP101 is provided to extend in the X direction. One end on the negative X direction side of the interconnect LP101 is coupled to the node ND1a. The other end on the positive X direction side of the interconnect LP101 is coupled to one end on the positive Y direction side of the interconnect LP102. The interconnect LP102 is provided to extend in the Y direction. The other end on the negative Y direction side of the interconnect LP102 is coupled to one end on the positive X direction side of the interconnect LP103. The interconnect LP103 is provided to extend in the X direction. The other end on the negative X direction side of the interconnect LP103 is coupled to one end on the negative Y direction side of the interconnect LP104.

The interconnect LP104 is provided to extend in the Y direction. The other end on the positive Y direction side of the interconnect LP104 is coupled to one end on the negative X direction side of the interconnect LP105. The other end of the interconnect LP104 is not in contact with the interconnect LP101. The interconnect LP105 is provided to extend in the X direction. The other end on the positive X direction side of the interconnect LP105 is not in contact with the interconnect LP102. The interconnect LP105 is provided alongside the interconnect LP101 in the Y direction. The interconnect LP106 is provided to extend in the X direction in a layer (second interconnect layer) above a layer (first interconnect layer) in which the interconnects LP101 to LP105 and LP107 to LP111 are provided. One end on the negative X direction side of the interconnect LP106 is coupled to the other end on the positive X direction side of the interconnect LP105 via a via plug. The other end on the positive X direction side of the interconnect LP106 is coupled to one end on the negative X direction side of the interconnect LP107 and one end on the positive Y direction side of the interconnect LP108 via a via plug.

The interconnect LP107 is provided to extend in the X direction. One end on the negative X direction side of the interconnect LP107 is not in contact with the interconnect LP102. The other end on the positive X direction side of the interconnect LP107 is coupled to the node ND3a. The interconnect LP108 is provided to extend in the Y direction. The other end on the negative Y direction side of the interconnect LP108 is coupled to one end on the positive X direction side of the interconnect LP109. The interconnect LP108 is provided alongside the interconnect LP102 in the X direction. The interconnect LP109 is provided to extend in the X direction. The other end on the negative X direction side of the interconnect LP109 is coupled to one end on the negative Y direction side of the interconnect LP110. The interconnect LP109 is provided alongside the interconnect LP103 in the Y direction.

The interconnect LP110 is provided to extend in the Y direction. The other end on the positive Y direction side of the interconnect LP110 is coupled to one end on the positive X direction side of the interconnect LP111. The other end of the interconnect LP110 is not in contact with the interconnect LP101. The interconnect LP110 is provided alongside the interconnect LP104 in the X direction. The interconnect LP111 is provided to extend in the X direction. The one end of the interconnect LP111 is in contact with neither of the interconnects LP104 and LP 105. The other end on the negative X direction side of the interconnect LP111 is coupled to the node ND4a.

In the T-coil TC1 configured as described above, the inductive element 112 is provided along the periphery of the inductive element 111.

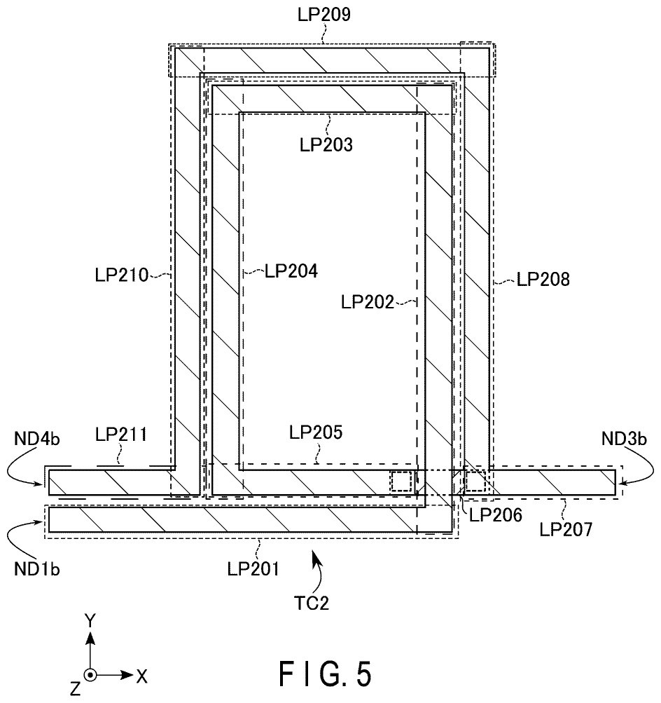

FIG. 5 is a plan view illustrating another example of the layout of the T-coil according to the first embodiment. As shown in FIG. 5, the T-coil TC2 is, for example, a two-turn planar coil having a square annular shape. The square annular shape may also be called a square shape, for example. The T-coil TC2 includes interconnects LP201 to LP211. The interconnects LP201 to LP205 and LP207 to LP211 are provided in a second interconnect layer. The interconnect LP206 is provided in a first interconnect layer. The interconnects LP201 to LP206 correspond to the inductive element 121. The interconnects LP208 to LP211 correspond to the inductive element 122. The interconnects LP205 and LP206 may be considered to correspond to the inductive element 122 rather than the inductive element 121.

The interconnect LP201 is provided to extend in the X direction. One end on the negative X direction side of the interconnect LP201 is coupled to the node ND1b. The other end on the positive X direction side of the interconnect LP201 is coupled to one end on the negative Y direction side of the interconnect LP202. The interconnect LP202 is provided to extend in the Y direction. The other end on the positive Y direction side of the interconnect LP202 is coupled to one end on the positive X direction side of the interconnect LP203. The interconnect LP203 is provided to extend in the X direction. The other end on the negative X direction side of the interconnect LP203 is coupled to one end on the positive Y direction side of the interconnect LP204.

The interconnect LP204 is provided to extend in the Y direction. The other end on the negative Y direction side of the interconnect LP204 is coupled to one end on the negative X direction side of the interconnect LP205. The other end of the interconnect LP204 is not in contact with the interconnect LP201. The interconnect LP205 is provided to extend in the X direction. The other end on the positive X direction side of the interconnect LP205 is not in contact with the interconnect LP202. The interconnect LP205 is provided alongside the interconnect LP201 in the Y direction. The interconnect LP206 is provided to extend in the X direction in a layer (first interconnect layer) below a layer (second interconnect layer) in which the interconnects LP201 to LP205 and LP207 to LP211 are provided. One end on the negative X direction side of the interconnect LP206 is coupled to the other end on the positive X direction side of the interconnect LP205 via a via plug. The other end on the positive X direction side of the interconnect LP206 is coupled to one end on the negative X direction side of the interconnect LP207 and one end on the negative Y direction side of the interconnect LP208 via a via plug.

The interconnect LP207 is provided to extend in the X direction. One end on the negative X direction side of the interconnect LP207 is not in contact with the interconnect LP202. The other end on the positive X direction side of the interconnect LP207 is coupled to the node ND3b. The interconnect LP208 is provided to extend in the Y direction. The other end on the positive Y direction side of the interconnect LP208 is coupled to one end on the positive X direction side of the interconnect LP209. The interconnect LP208 is provided alongside the interconnect LP202 in the X direction. The interconnect LP209 is provided to extend in the X direction. The other end on the negative X direction side of the interconnect LP209 is coupled to one end on the positive Y direction side of the interconnect LP210. The interconnect LP209 is provided alongside the interconnect LP203 in the Y direction.

The interconnect LP210 is provided to extend in the Y direction. The other end on the negative Y direction side of the interconnect LP210 is coupled to one end on the positive X direction side of the interconnect LP211. The other end of the interconnect LP210 is not in contact with the interconnect LP201. The interconnect LP210 is provided alongside the interconnect LP204 in the X direction. The interconnect LP211 is provided to extend in the X direction. The one end of the interconnect LP211 is in contact with neither of the interconnects LP204 and LP205. The other end on the negative X direction side of the interconnect LP211 is coupled to the node ND4b.

In the T-coil TC2 configured as described above, the inductive element 122 is provided along the periphery of the inductive element 121.

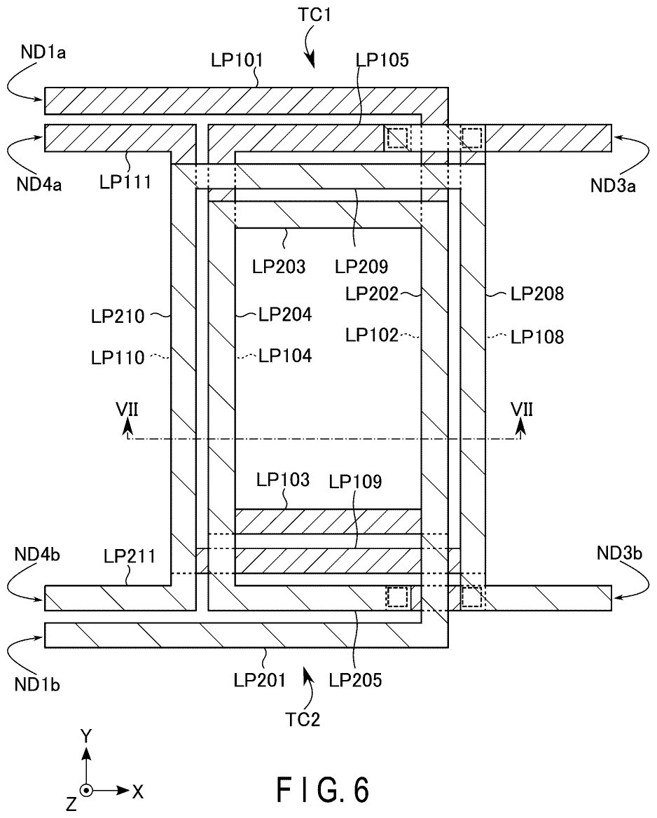

FIG. 6 is a plan view illustrating a layout of the T-coil pair according to the first embodiment. The T-coil TC1 provided mainly in the first interconnect layer and the T-coil TC2 provided mainly in the second interconnect layer are provided to overlap with each other in XY planar view and not to cause a short circuit.

More specifically, a part of the interconnect LP102 and a part of the interconnect LP202 overlap with each other in XY planar view. A part of the interconnect LP104 and a part of the interconnect LP204 overlap with each other in XY planar view. A part of the interconnect LP108 and a part of the interconnect LP208 overlap with each other in XY planar view. A part of the interconnect LP110 and a part of the interconnect LP210 overlap with each other in XY planar view. In addition, the interconnects LP101, LP105, LP209, and LP203 are provided side by side in the Y direction in XY planar view. The interconnects LP103, LP109, LP205, and LP201 are provided side by side in the Y direction in XY planar view.

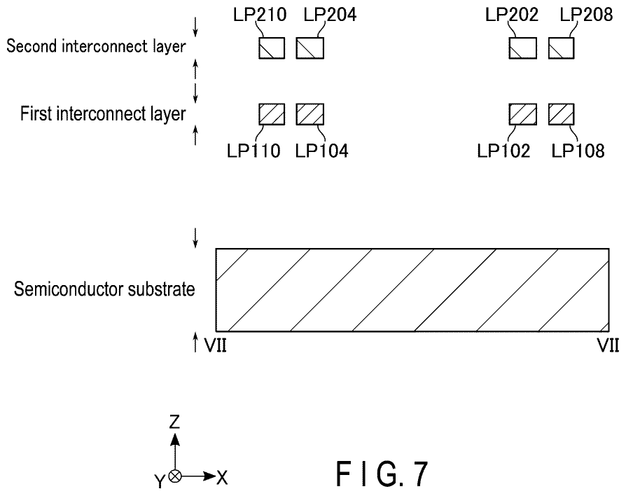

FIG. 7 is a cross-sectional view illustrating the layout of the T-coil pair according to the first embodiment. FIG. 7 shows a cross-sectional structure of a portion corresponding to line VII-VII shown in FIG. 6. The first interconnect layer is provided above the semiconductor substrate, and the second interconnect layer is provided above the first interconnect layer. The semiconductor substrate and the first interconnect layer are insulated by an interlayer insulating film (not shown), and the first interconnect layer and the second interconnect layer are also insulated by an interlayer insulating film (not shown).

In an area shown in FIG. 7, the interconnects LP102, LP104, LP108, and LP110 are provided in the first interconnect layer. In the area shown in FIG. 7, the interconnects LP202, LP204, LP208, and LP210 are provided in the second interconnect layer. The interconnect LP202 is provided above the interconnect LP102 in the Z direction. The interconnect LP204 is provided above the interconnect LP104 in the Z direction. The interconnect LP208 is provided above the interconnect LP108 in the Z direction. The interconnect LP210 is provided above the interconnect LP110 in the Z direction.

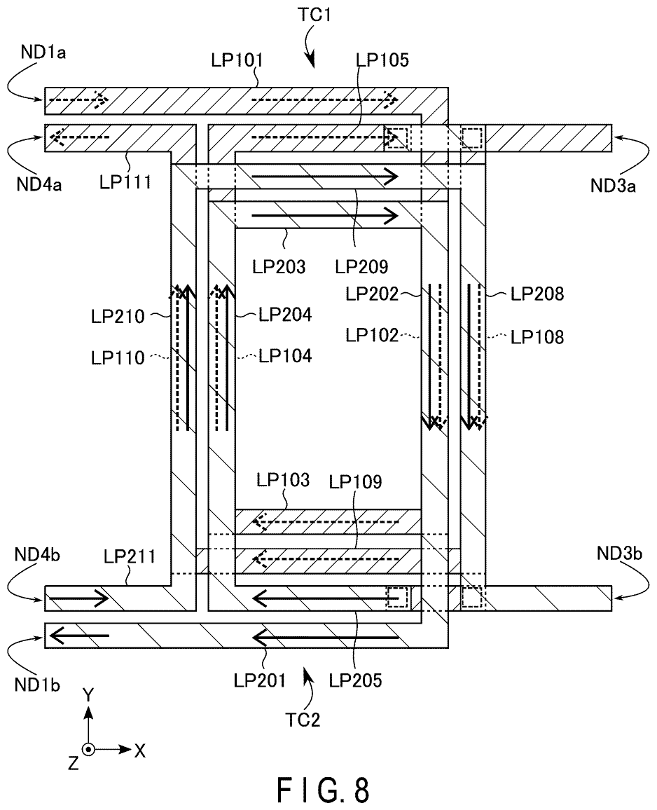

FIG. 8 is a plan view illustrating directions of signal currents flowing through the T-coil pair according to the first embodiment. An example of the directions of signal currents flowing through the T-coils TC1 and TC2 will be described with reference to FIG. 8. In FIG. 8, the directions of signal currents flowing through the T-coils TC1 and TC2 are indicated by arrows. The direction of signal current flowing through the T-coil TC1 is indicated by dashed arrow, and the direction of signal current flowing through the T-coil TC2 is indicated by solid arrow. Here is a description of a case in which a signal current flows from the node ND1a of the T-coil TC1 to the node ND4a thereof. In this case, a signal applied to the receiving circuit 100 is a differential signal and thus the direction of a signal current flowing through the T-coil TC2 is opposite to that of the signal current flowing through the T-coil TC1. That is, in the T-coil TC2, a signal current flows from the node ND4b to the node ND1b.

In the T-coil TC1, a signal current flows from the node ND1a to the node ND4a. In each of the interconnects LP101 to LP111, a signal current flows from one end to the other end thereof. In the T-coil TC2, a signal current flows from the node ND4b to the node ND1b. In each of the interconnects LP201 to LP211, a signal current flows from the other end to one end thereof.

Here is a description of directions of signal currents in a case where the interconnects overlap or are arranged side by side in XY planar view. In each of the interconnects LP102 and LP202, a signal current flows from the positive Y direction toward the negative Y direction in FIG. 8. In each of the interconnects LP104 and LP204, a signal current flows from the negative Y direction toward the positive Y direction in FIG. 8. In each of the interconnects LP108 and LP208, a signal current flows from the positive Y direction toward the negative Y direction in FIG. 8. In each of the interconnects LP110 and LP210, a signal current flows from the negative Y direction to the positive Y direction in FIG. 8. In each of the interconnects LP101, LP105, LP209, and LP203, a signal current flows from the negative X direction toward the positive X direction in FIG. 8. In each of the interconnects LP103, LP109, LP205, and LP201, a signal current flows from the positive X direction toward the negative X direction in FIG. 8. Thus, the directions of signal currents flowing through the areas where the interconnects overlap or are arranged side by side in XY planar view are aligned in the T-coil pair TCP according to the first embodiment.

### <1-2> Advantages

The semiconductor circuit according to the first embodiment described above makes it possible to suppress an increase in a mounting area of the circuit. The advantages of the semiconductor circuit according to the first embodiment will be described below in detail.

The semiconductor circuit according to the first embodiment includes a T-coil pair. The T-coil pair, to which a differential signal is applied, is mounted by, for example, symmetrically laying out a T-coil to which a positive polarity signal is applied and a T-coil to which a negative polarity signal is applied. It is desirable to decrease the area of the T-coil pair.

The T-coil pair TCP according to the first embodiment is laid out so that the T-coil TC1 to which a positive polarity signal is applied and the T-coil TC2 to which a negative polarity signal is applied overlap with each other in XY planar view. Thus, the semiconductor circuit according to the first embodiment can suppress an increase in the mounting area more than in a case where the T-coils are laid out side by side.

In the T-coil pair TCP according to the first embodiment, furthermore, the T-coils TC1 and TC2 are mounted to overlap with each other in XY planar view so that the directions of signal currents are aligned when a differential signal is applied thereto. Thus, when a differential signal is applied to the T-coil pair TCP, the overlapping T-coils TC1 and TC2 are inductively coupled to each other so as to strengthen the inductance. Therefore, the T-coil pair TCP according to the first embodiment can increase the inductance per unit area more than in a case where the T-coils do not overlap with each other. In the semiconductor circuit according to the first embodiment, the increase in the inductance of the T-coil pair per unit area makes it possible to suppress an increase in the mounting area of the T-coil pair having the same inductance.

The semiconductor circuit according to the first embodiment also makes it possible to improve the performance of the T-coil pair instead of suppressing an increase in the mounting area. For example, the semiconductor circuit according to the first embodiment can implement a T-coil pair having a smaller resistive component by laying out the T-coil pair using interconnects with larger width by making use of an area obtained by laying out the T-coils to overlap with each other in XY planar view. If the resistive component of the T-coil pair decreases, for example, the band of the semiconductor circuit according to the first embodiment can be broadened.

### <2> Second Embodiment

A configuration of a semiconductor circuit according to a second embodiment differs in the shape of a T-coil pair from that of the semiconductor circuit according to the first embodiment. Below is a description of differences of the semiconductor circuit of the second embodiment from that of the first embodiment.

The semiconductor circuit according to the second embodiment and the semiconductor circuit according to the first embodiment are the same in terms of the description of the circuit diagram and different in the layout thereof. In the second embodiment, inductive elements 111 and 112 each is referred to as a T-coil TC1a, and inductive elements 121 and 122 each is referred to as a T-coil TC2a. A pair of the T-coils TC1a and TC2a is referred to as a T-coil pair TCPa.

### <2-1> Configuration

### <2-1-1> Layout of T-Coil Pair

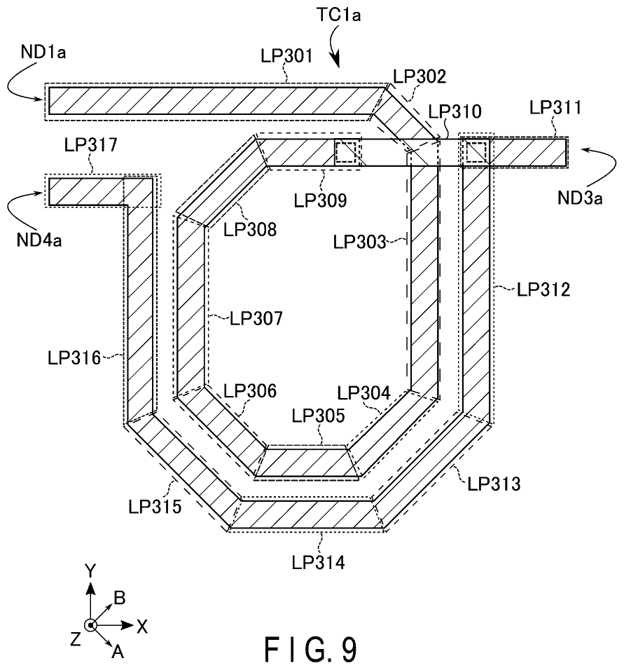

FIG. 9 is a plan view illustrating an example of the layout of a T-coil according to the second embodiment. As shown in FIG. 9, the T-coil TC1a is, for example, a two-turn planar coil having an octagonal annular shape. The octagonal annular shape is also referred to as an octagonal shape, for example. The T-coil TC1a includes interconnects LP301 to LP317. The interconnects LP301 to LP309 and LP311 to LP317 are provided in a first interconnect layer. The interconnect LP310 is provided in a second interconnect layer. The interconnects LP301 to LP310 correspond to the inductive element 111. The interconnects LP312 to LP317 correspond to the inductive element 112. The interconnects LP309 and LP310 may be considered to correspond to the inductive element 112 rather than the inductive element 111.

In the XY plane, a direction in which the X axis is rotated clockwise by, for example, 45 degrees is defined as an A direction, and a direction in which the X axis is rotated counterclockwise by, for example, 45 degrees is defined as a B direction. Further, a direction from the upper left of the figure toward the lower right thereof is defined as a positive A direction, and a direction from the lower right of the figure toward the upper left thereof is defined as a negative A direction. A direction from the lower left of the figure toward the upper right thereof is defined as a positive B direction, and a direction from the upper right of the figure toward the lower left thereof is defined as a negative B direction.

The interconnect LP301 is provided to extend in the X direction. One end on the negative X direction side of the interconnect LP301 is coupled to a node ND1a. The other end on the positive X direction side of the interconnect LP301 is coupled to one end on the negative A direction side of the interconnect LP302. The interconnect LP 302 is provided to extend in the A direction. The other end on the positive A direction side of the interconnect LP302 is coupled to one end on the positive Y direction side of the interconnect LP303. The interconnect LP303 is provided to extend in the Y direction. The other end on the negative Y direction side of the interconnect LP303 is coupled to one end on the positive B direction side of the interconnect LP304.

The interconnect LP304 is provided to extend in the B direction. The other end on the negative B direction side of the interconnect LP304 is coupled to one end on the positive X direction side of the interconnect LP305. The interconnect LP 305 is provided to extend in the X direction. The other end on the negative X direction side of the interconnect LP305 is coupled to one end on the positive A direction side of the interconnect LP306. The interconnect LP306 is provided to extend in the A direction. The other end on the negative A direction side of the interconnect LP306 is coupled to one end on the negative Y direction side of the interconnect LP307.

The interconnect LP307 is provided to extend in the Y direction. The other end on the positive Y direction side of the interconnect LP307 is coupled to one end on the negative B direction side of the interconnect LP308. The interconnect LP308 is provided to extend in the B direction. The other end on the positive B direction side of the interconnect LP308 is coupled to one end on the negative X direction side of the interconnect LP309. The other end of the interconnect LP308 is not in contact with the interconnect LP301. The interconnect LP309 is provided to extend in the X direction. The other end on the positive X direction side of the interconnect LP309 is coupled to one end on the negative X direction side of the interconnect LP310 via a via plug. The other end of the interconnect LP309 is in contact with neither of the interconnects LP302 and LP303. The interconnect LP309 is provided alongside the interconnect LP301 in the Y direction.

The interconnect LP310 is provided to extend in the X direction. The other end on the positive X direction side of the interconnect LP310 is coupled to one end on the negative X direction side of the interconnect LP311 and one end on the positive Y direction side of the interconnect LP312 via a via plug. The interconnect LP311 is provided to extend in the X direction. The other end on the positive X direction side of the interconnect LP311 is coupled to a node ND3a. The one end of the interconnect LP311 is in contact with neither of the interconnects LP302 and LP303. The interconnect LP312 is provided to extend in the Y direction. The other end on the negative Y direction side of the interconnect LP312 is coupled to one end on the positive B direction side of the interconnect LP313. The interconnect LP312 is provided alongside the interconnect LP303 in the X direction.

The interconnect LP313 is provided to extend in the B direction. The other end on the negative B direction side of the interconnect LP313 is coupled to one end on the positive X direction side of the interconnect LP314. The interconnect LP313 is provided alongside the interconnect LP304 in the A direction. The interconnect LP314 is provided to extend in the X direction. The other end on the negative X direction side of the interconnect LP314 is coupled to one end on the positive A direction side of the interconnect LP315. The interconnect LP314 is provided alongside the interconnect LP305 in the Y direction. The interconnect LP315 is provided to extend in the A direction. The other end in the negative A direction side of the interconnect LP315 is coupled to one end on the negative Y direction side of the interconnect LP316. The interconnect LP315 is provided alongside the interconnect LP306 in the B direction.

The interconnect LP316 is provided to extend in the Y direction. The other end on the positive Y direction side of the interconnect LP316 is coupled to one end on the positive X direction side of the interconnect LP317. The other end of the interconnect LP316 is not in contact with the interconnect LP301. The interconnect LP316 is provided alongside the interconnect LP307 in the X direction. The interconnect LP317 is provided to extend in the X direction. The other end on the negative X direction side of the interconnect LP317 is coupled to a node ND4a. The one end of the interconnect LP317 is not in contact with the interconnect LP308.

In the T-coil TC1a configured as described above, the inductive element 112 is provided along the periphery of the inductive element 111.

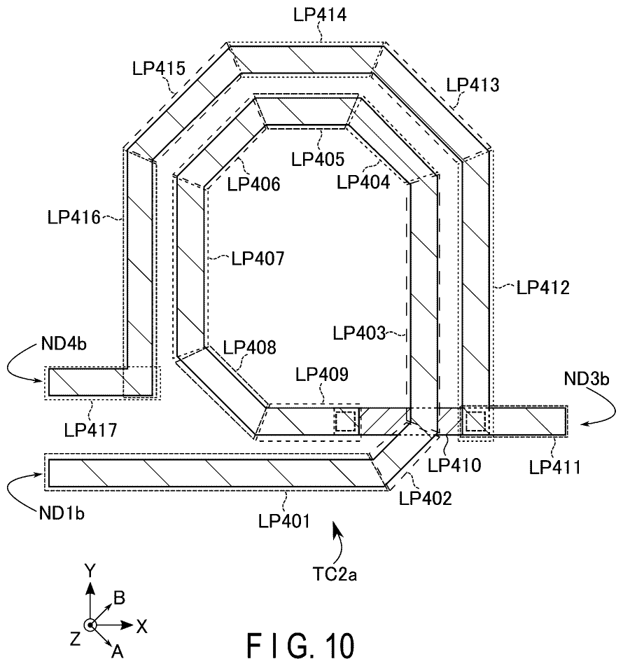

FIG. 10 is a plan view illustrating another example of the layout of the T-coil according to the second embodiment. As shown in FIG. 10, the T-coil TC2a is, for example, a two-turn planar coil having an octagonal annular shape. The octagonal annular shape is also referred to as an octagonal shape, for example. The T-coil TC2a includes interconnects LP401 to LP417. The interconnects LP401 to LP409 and LP411 to LP417 are provided in the second interconnect layer. The interconnect LP410 is provided in the first interconnect layer. The interconnects LP401 to LP410 correspond to the inductive element 121. The interconnects LP412 to LP417 correspond to the inductive element 122. The interconnects LP409 and LP410 may be considered to correspond to the inductive element 122 rather than the inductive element 121.

The interconnect LP401 is provided to extend in the X direction. One end on the negative X direction side of the interconnect LP401 is coupled to a node ND1b. The other end on the positive X direction side of the interconnect LP401 is coupled to one end on the negative B direction side of the interconnect LP402. The interconnect LP402 is provided to extend in the B direction. The other end on the positive B direction side of the interconnect LP402 is coupled to one end on the negative Y direction side of the interconnect LP403. The interconnect LP403 is provided to extend in the Y direction. The other end on the positive Y direction side of the interconnect LP403 is coupled to one end on the positive A direction side of the interconnect LP404.

The interconnect LP404 is provided to extend in the A direction. The other end on the negative A direction side of the interconnect LP404 is coupled to one end on the positive X direction side of the interconnect LP405. The interconnect LP405 is provided to extend in the X direction. The other end on the negative X direction side of the interconnect LP405 is coupled to one end on the positive B direction side of the interconnect LP406. The interconnect LP406 is provided to extend in the B direction. The other end on the negative B direction side of the interconnect LP406 is coupled to one end on the positive Y direction side of the interconnect LP407.

The interconnect LP407 is provided to extend in the Y direction. The other end on the negative Y direction side of the interconnect LP407 is coupled to one end on the negative A direction side of the interconnect LP408. The interconnect LP408 is provided to extend in the A direction. The other end on the positive A direction side of the interconnect LP408 is coupled to one end on the negative X direction side of the interconnect LP409. The other end of the interconnect LP408 is not in contact with the interconnect LP401. The interconnect LP409 is provided to extend in the X direction. The other end on the positive X direction side of the interconnect LP409 is coupled to one end on the negative X direction side of the interconnect LP410 via a via plug. The other end of the interconnect LP409 is in contact with neither of the interconnects LP402 and LP403. The interconnect LP409 is provided alongside the interconnect LP401 in the Y direction.

The interconnect LP410 is provided to extend in the X direction. The other end on the positive X direction side of the interconnect LP410 is coupled to one end on the negative X direction side of the interconnect LP411 and one end on the negative Y direction side of the interconnect LP412 via a via plug. The interconnect LP411 is provided to extend in the X direction. The other end on the positive X direction side of the interconnect LP411 is coupled to a node ND3b. The one end of the interconnect LP411 is in contact with neither of the interconnects LP402 and LP403. The interconnect LP412 is provided to extend in the Y direction. The other end on the positive Y direction side of the interconnect LP412 is coupled to one end on the positive A direction side of the interconnect LP413. The interconnect LP412 is provided alongside the interconnect LP403 in the X direction.

The interconnect LP413 is provided to extend in the A direction. The other end on the negative A direction side of the interconnect LP413 is coupled to one end on the positive X direction side of the interconnect LP414. The interconnect LP413 is provided alongside the interconnect LP404 in the B direction. The interconnect LP414 is provided to extend in the X direction. The other end on the negative X direction side of the interconnect LP414 is coupled to one end on the positive B direction side of the interconnect LP415. The interconnect LP414 is provided alongside the interconnect LP405 in the Y direction. The interconnect LP415 is provided to extend in the B direction. The other end on the negative B direction side of the interconnect LP415 is coupled to one end on the positive Y direction side of the interconnect LP416. The interconnect LP415 is provided alongside the interconnect LP406 in the A direction.

The interconnect LP416 is provided to extend in the Y direction. The other end on the negative Y direction side of the interconnect LP416 is coupled to one end on the positive X direction side of the interconnect LP417. The other end of the interconnect LP416 is not in contact with the interconnect LP401. The interconnect LP416 is provided alongside the interconnect LP407 in the X direction. The interconnect LP417 is provided to extend in the X direction. The other end on the negative X direction side of the interconnect LP417 is coupled to a node ND4b. The one end of the interconnect LP417 is not in contact with the interconnect LP408.

In the T-coil TC2a configured as described above, the inductive element 122 is provided along the periphery of the inductive element 121.

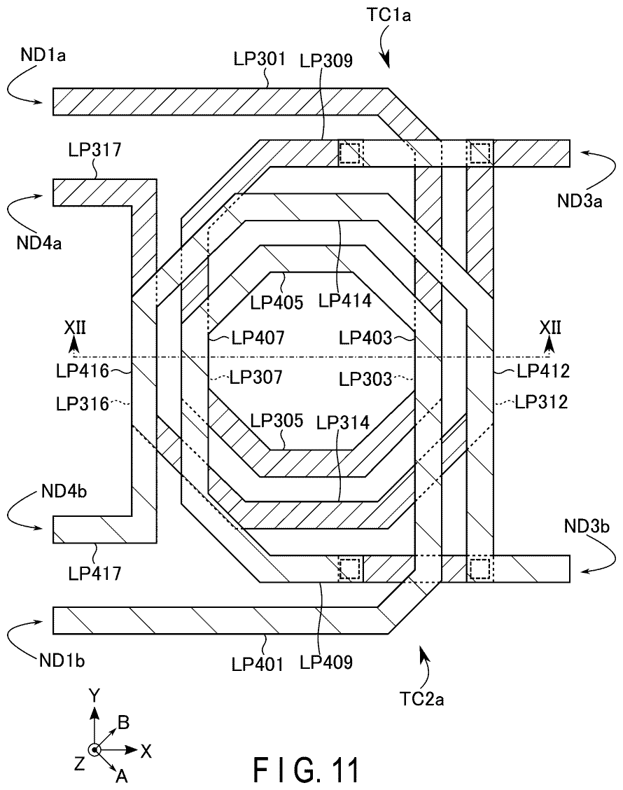

FIG. 11 is a plan view illustrating the layout of the T-coil pair according to the second embodiment. The T-coil TC1a provided mainly in the first interconnect layer and the T-coil TC2a provided mainly in the second interconnect layer are provided to overlap with each other in XY planar view and not to cause a short circuit.

For example, a part of the interconnect LP303 and a part of the interconnect LP403 overlap with each other in XY planar view. A part of the interconnect LP307 and a part of the interconnect LP407 overlap with each other in XY planar view. A part of the interconnect LP312 and a part of the interconnect LP412 overlap with each other in XY planar view. A part of the interconnect LP316 and a part of the interconnect LP416 overlap with each other in XY planar view. The interconnects LP301, LP309, LP414, and LP405 are arranged side by side in the Y direction in XY planar view. The interconnects LP305, LP314, LP409, and LP401 are arranged side by side in the Y direction in XY planar view.

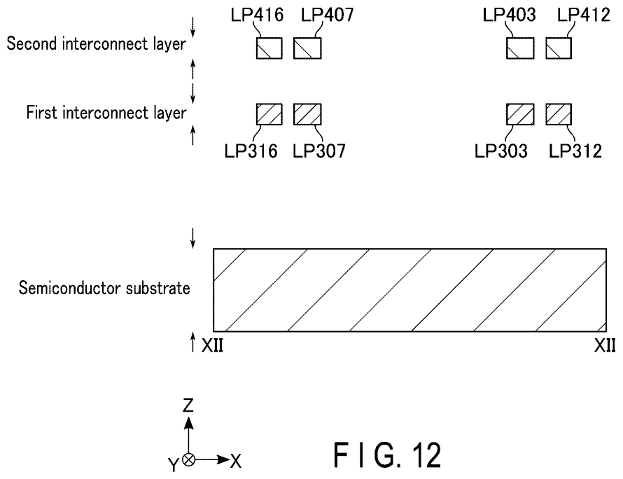

FIG. 12 is a cross-sectional view illustrating the layout of the T-coil pair according to the second embodiment. FIG. 12 shows a cross-sectional structure of a portion corresponding to line XII-XII shown in FIG. 11. The first interconnect layer is provided above the semiconductor substrate, and the second interconnect layer is provided above the first interconnect layer. The semiconductor substrate and the first interconnect layer are insulated by an interlayer insulating film (not shown), and the first interconnect layer and the second interconnect layer are also insulated by an interlayer insulating film (not shown).

In an area shown in FIG. 12, the interconnects LP303, LP307, LP312, and LP316 are provided in the first interconnect layer. In the area shown in FIG. 12, the interconnects LP403, LP407, LP412, and LP416 are provided in the second interconnect layer. The interconnect LP403 is provided above the interconnect LP303 in the Z direction. The interconnect LP407 is provided above the interconnect LP307 in the Z direction. The interconnect LP412 is provided above the interconnect LP312 in the Z direction. The interconnect LP416 is provided above the interconnect LP316 in the Z direction.

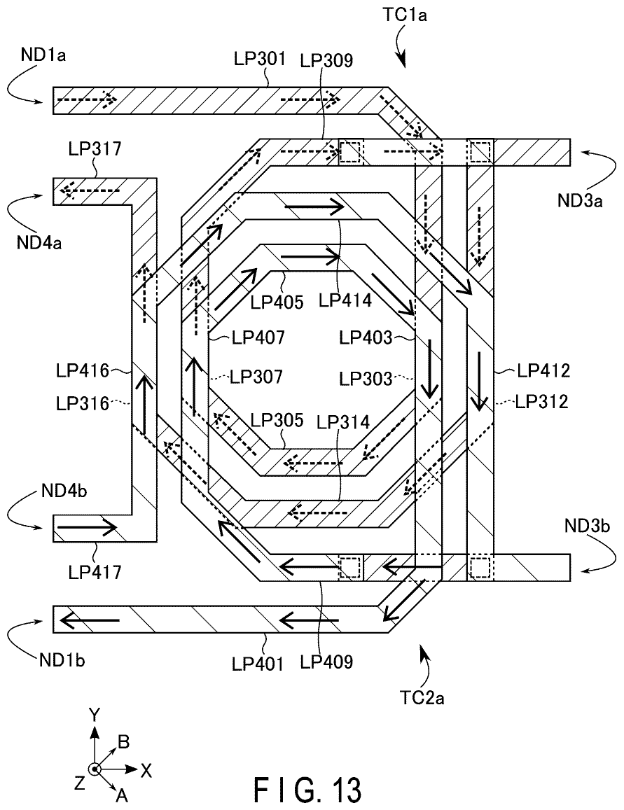

FIG. 13 is a plan view illustrating directions of signal currents flowing through the T-coil pair according to the second embodiment. An example of the directions of signal currents flowing through the T-coils TC1a and TC2a will be described with reference to FIG. 13. In FIG. 13, the directions of signal currents flowing through the T-coils TC1a and TC2a are indicated by arrows. The direction of signal current flowing through the T-coil TC1a is indicated by dashed arrow, and the direction of signal current flowing through the T-coil TC2a are indicated by solid arrow. Here is a description of a case in which a signal current flows from the node ND1a of the T-coil TC1a to the node ND4a thereof. In this case, a signal applied to the receiving circuit 100 is a differential signal and thus the direction of a signal current flowing through the T-coil TC2a is opposite to that of the signal current flowing through the T-coil TC1a. That is, in the T-coil TC2a, a signal current flows from the node ND4b to the node ND1b.

In the T-coil TC1a, a signal current flows from the node ND1a to the node ND4a. In each of the interconnects LP301 to LP317, a signal current flows from one end to the other end thereof. In the T-coil TC2a, a signal current flows from the node ND4b to the node ND1b. In each of the interconnects LP401 to LP417, a signal current flows from the other end to one end thereof.

Here is a description of some examples of directions of signal currents in a case where the interconnects overlap or are arranged side by side in XY planar view. In each of the interconnects LP303 and LP403, a signal current flows from the positive Y direction toward the negative Y direction in FIG. 13. In each of the interconnects LP307 and LP407, a signal current flows from the negative Y direction toward the positive Y direction in FIG. 13. In each of the interconnects LP312 and LP412, a signal current flows from the positive Y direction toward the negative Y direction in FIG. 13. In each of the interconnects LP316 and LP416, a signal current flows from the negative Y direction to the positive Y direction in FIG. 13. In each of the interconnects LP301, LP309, LP414, and LP405, a signal current flows from the negative X direction toward the positive X direction in FIG. 13. In each of the interconnects LP305, LP314, LP409, and LP401, a signal current flows from the positive X direction toward the negative X direction in FIG. 13. Thus, the directions of signal currents flowing through the areas where the interconnects overlap or are arranged side by side in XY planar view are aligned in the T-coils TC1a and TC2a according to the second embodiment.

### <2-2> Advantages

Like the semiconductor circuit according to the first embodiment, the semiconductor circuit according to the second embodiment described above makes it possible to suppress an increase in the mounting area of the circuit.

The first and second embodiments differ in the shape of the T-coils. Specifically, the T-coils have a square annular shape in the first embodiment, and they have an octagonal annular shape in the second embodiment. Even if the T-coils have the octagonal annular shape in the semiconductor circuit according to the second embodiment, it is possible to suppress an increase in the mounting area, as in the semiconductor circuit according to the first embodiment, by overlapping the T-coils in XY planar view. Like in the semiconductor circuit according to the first embodiment, in the semiconductor circuit according to the second embodiment, if a differential signal is applied to the T-coil pair, the overlapping T-coils in XY planar view are inductively coupled together so as to strengthen the inductance. Therefore, like the semiconductor circuit according to the first embodiment, the semiconductor circuit according to the second embodiment makes it possible to increase the inductance per unit area and suppress an increase in the mounting are.

### <3> Modifications

In the above embodiments, the receiving circuit is described as the example of the semiconductor circuit according to the embodiments. The semiconductor circuit according to the embodiments may be a circuit other than the receiving circuit, such as a termination circuit of a receiver.

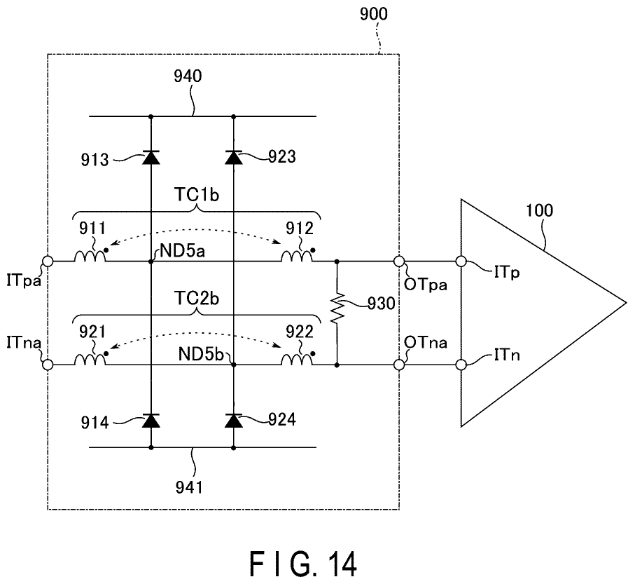

FIG. 14 is a circuit diagram showing an example of a configuration of a termination circuit and a receiving circuit according to a first modification. As shown in FIG. 14, a termination circuit 900 includes two input terminals ITpa and ITna, two output terminals OTpa and OTna, a plurality of inductive elements 911, 912, 921, and 922, a plurality of diodes 913, 914, 923, and 924, a resistive element 930, and a plurality of power supply lines 940 and 941.

The termination circuit 900 of the first modification is a differential input/output type termination circuit. The input terminal ITpa is configured to receive a positive polarity signal. The input terminal ITna is configured to receive a negative polarity signal. The output terminal OTpa is configured to output a positive polarity signal. The output terminal OTna is configured to output a negative polarity signal.

Each of the inductive elements 911, 912, 921 and 922 is, for example, an on-chip coil.

One end of the inductive element 911 is electrically coupled to the input terminal ITpa. The other end of the inductive element 911 is electrically coupled to a node ND5a. The polarity of mutual induction of the inductive element 911 is toward the node ND5a side of the inductive element 911 (toward the other end of the inductive element 911).

One end of the inductive element 912 is electrically coupled to the node ND5a. The other end of the inductive element 912 is electrically coupled to the output terminal OTpa. The polarity of mutual induction of the inductive element 912 is toward the output terminal OTpa side of the inductive element 912 (toward the other end of the inductive element 912).

One end of the inductive element 921 is electrically coupled to the input terminal ITna. The other end of the inductive element 921 is electrically coupled to a node ND5b. The polarity of mutual induction of the inductive element 921 is toward the node ND5b side of the inductive element 921 (toward the other end of the inductive element 921).

One end of the inductive element 922 is electrically coupled to the node ND5b. The other end of the inductive element 922 is electrically coupled to the output terminal OTna. The polarity of mutual induction of the inductive element 922 is toward the output terminal OTna side of the inductive element 922 (toward the other end of the inductive element 922).

The anode of the diode 913 is electrically coupled to the node ND5a. The cathode of the diode 913 is electrically coupled to the power supply line 940 on the high potential side of the termination circuit 900. A power supply voltage VDD is applied to the power supply line 940.

The anode of the diode 914 is electrically coupled to the power supply line 941 on the low potential side of the termination circuit 900. A ground voltage VGND is applied to the power supply line 941. The ground voltage VGND is a reference potential based on the termination circuit 900 operates. The cathode of the diode 914 is electrically coupled to the node ND5a.

The anode of the diode 923 is electrically coupled to the node ND5b. The cathode of the diode 923 is electrically coupled to the power supply line 940.

The anode of the diode 924 is electrically coupled to the power supply line 941. The cathode of the diode 924 is electrically coupled to the node ND5b.

One end of the resistive element 930 is electrically coupled to the output terminal OTpa. The other end of the resistive element 930 is electrically coupled to the output terminal OTna.

The output terminal OTpa of the termination circuit 900 is electrically coupled to the input terminal ITp of the receiving circuit 100. The output terminal OTna of the termination circuit 900 is electrically coupled to the input terminal ITn of the receiving circuit 100. Thus, the differential signals applied to the input terminals ITpa and ITna of the termination circuit 900 are transmitted to the input terminals ITp and ITn of the receiving circuit 100 via an internal circuit of the termination circuit 900.

Hereinafter, each of the inductive elements 911 and 912 will be referred to as a T-coil TC1b, and each of the inductive elements 921 and 922 will be referred to as a T-coil TC2b. In addition, the combination of the T-coils TC1b and TC2b will be referred to as a T-coil pair TCPb.

By laying out the T-coil pair TCPb according to the first modification like the t-coil pair according to the first embodiment or the second embodiment, the termination circuit 900 according to the first modification can obtain the same advantages as those of the receiving circuit according to the first embodiment or the second embodiment.

In the first modification, a case in which the T-coil pair is included in the termination circuit of the receiver is described. The termination circuit including the T-coil pair may be incorporated into a circuit other than the receiver and may be used in a transmitter, for example.

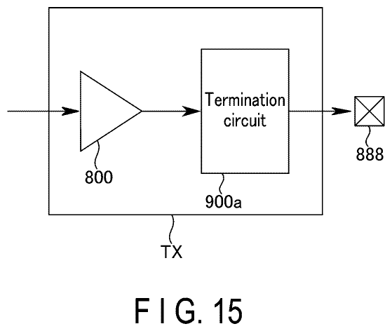

FIG. 15 is a schematic diagram showing an example of a configuration of a transmitter according to a second modification. As shown in FIG. 15, a transmitter TX includes a termination circuit 900a and a transmission circuit 800.

The termination circuit 900a is coupled to a transmission terminal (transmission node) 888 of the memory controller 50. The termination circuit 900a secures impedance matching of signal lines on the output side of the transmitter TX. Thus, the termination circuit 900a suppresses reflection from occurring in the signal lines on the output side of the transmitter TX.

The transmission circuit 800 amplifies the signal input from the outside of the transmission circuit 800 and outputs the amplified signal to the transmission terminal (transmission node) 888 via the termination circuit 900a.

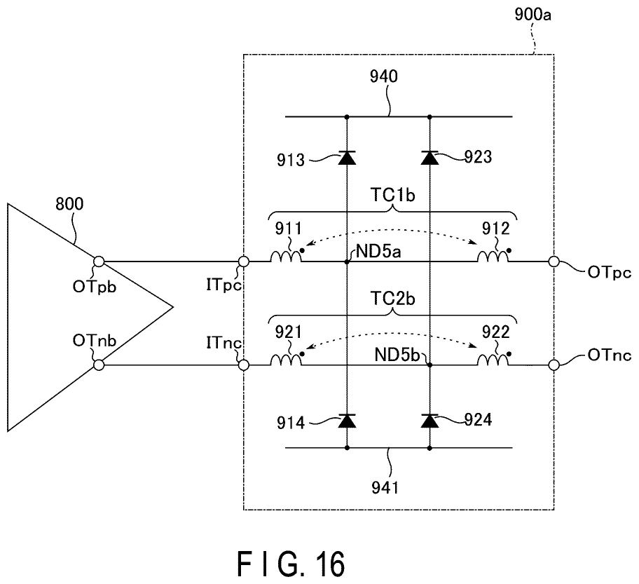

FIG. 16 is a circuit diagram showing an example of a configuration of the transmission circuit and termination circuit according to the second modification. As shown in FIG. 16, in the termination circuit 900a according to the second modification, the input terminal ITpa of the termination circuit 900 according to the first modification is replaced with an input terminal ITpc, the input terminal ITna thereof is replaced with an input terminal ITnc, the output terminal OTpa thereof is replaced with an output terminal OTpc, the output terminal OTna thereof is replaced with an output terminal OTnc, and the resistive element 930 thereof is removed. Other configurations of the termination circuit 900a according to the second modification are similar to that of the termination circuit 900 according to the first modification. The transmission circuit 800 includes an output terminal OTpb and an output terminal OTnb.

The output terminal OTpb of the transmission circuit 800 outputs a positive polarity signal. The output terminal OTnb of the transmission circuit 800 outputs a negative polarity signal.

The output terminal OTpb of the transmission circuit 800 and the input terminal ITpc of the termination circuit 900a are electrically coupled to each other. The output terminal OTnb of the transmission circuit 800 and the input terminal ITnc of the termination circuit 900a are electrically coupled to each other. Thus, a differential signal output from the transmission circuit 800 is output from the output terminals OTpc and OTnc of the termination circuit 900a via an internal circuit of the termination circuit 900a.

By laying out the T-coil pair TCPb according to the second modification like the T-coil pair according to the first embodiment or the second embodiment, the termination circuit 900a according to the second modification can obtain the same advantages as those of the receiving circuit according to the first embodiment or the second embodiment.

In the present specification, “one end of the current path of the transistor” corresponds to a source or a drain of the MOS transistor. “The other end of the current path of the transistor” corresponds to the drain or the source of the MOS transistor.

In the present specification, the term “coupled” indicates an electrical coupling and does not exclude any element interposed between coupled elements. Also, the phrase “electrically coupled” may indicate coupled elements between which an insulator is interposed if the coupled elements can operate in the same manner as electrically coupled ones.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor circuit comprising:
a semiconductor substrate;
a first T-coil provided apart from the semiconductor substrate and including a first inductive element and a second inductive element which are coupled in series; and
a second T-coil provided apart from the semiconductor substrate and including a third inductive element and a fourth inductive element which are coupled in series,
wherein
a part of the first T-coil is provided at a first position in a vertical direction from a surface of the semiconductor substrate,
a part of the second T-coil is provided at a second position in the vertical direction from the surface to overlap with the part of the first T-coil in the vertical direction,
in the vertical direction, a first distance from the semiconductor substrate to the first position is different from a second distance from the semiconductor substrate to the second position,
the first T-coil is configured to receive a first signal having a first polarity of a differential signal, and
the second T-coil is configured to receive a second signal having a second polarity different from the first polarity of the differential signal.

2. The semiconductor circuit according to claim 1, wherein each of the first T-coil and the second T-coil has one of a square annular shape and an octagonal annular shape.

3. The semiconductor circuit according to claim 1, wherein a direction of a current of the first signal flowing through the first T-coil and a direction of a current of the second signal flowing through the second T-coil are aligned in an area where the part of the first T-coil and the part of the second T-coil overlap with each other in the vertical direction.

4. The semiconductor circuit according to claim 1, wherein
the surface of the semiconductor substrate is parallel to a plane defined by a first direction and a second direction that intersects the first direction, and
the first T-coil includes:
a first portion having one end and other end and extending in the first direction;
a second portion having one end and other end and extending in the second direction, the one end of the second portion being coupled to the other end of the first portion;
a third portion having one end and other end and extending in the first direction, the one end of the third portion being coupled to the other end of the second portion;
a fourth portion having one end and other end, extending in the second direction, and provided so as not to be in contact with the first portion, the one end of the fourth portion being coupled to the other end of the third portion;
a fifth portion having one end and other end, extending in the first direction in parallel with the first portion, and provided so as not to be in contact with the second portion, the one end of the fifth portion being coupled to the other end of the fourth portion;
a sixth portion having one end and other end, extending in the first direction, and provided at a position different from a position of the second portion, the one end of the sixth portion being electrically coupled to the other end of the fifth portion;
a seventh portion having one end and other end and extending in the second direction in parallel with the second portion, the one end of the seventh portion being electrically coupled to the other end of the sixth portion;
an eighth portion having one end and other end and extending in the first direction in parallel with the third portion, the one end of the eighth portion being coupled to the other end of the seventh portion;
a ninth portion having one end and other end, extending in the second direction in parallel with the fourth portion, and provided so as not to be in contact with the first portion, the one end of the ninth portion being coupled to the other end of the eighth portion; and
a tenth portion having one end and other end, extending in the first direction in parallel with the first portion, and provided so as not to be in contact with the fourth portion, the one end of the tenth portion being coupled to the other end of the ninth portion.

5. The semiconductor circuit according to claim 4, wherein the second T-coil includes:
an eleventh portion having one end and other end and extending in the first direction;
a twelfth portion having one end and other end and extending in the second direction, the one end of the twelfth portion being coupled to the other end of the eleventh portion;
a thirteenth portion having one end and other end and extending in the first direction, the one end of the thirteenth portion being coupled to the other end of the twelfth portion;
a fourteenth portion having one end and other end, extending in the second direction, and provided so as not to be in contact with the eleventh portion, the one end of the fourteenth portion being coupled to the other end of the thirteenth portion;
a fifteenth portion having one end and other end, extending in the first direction in parallel with the eleventh portion, and provided so as not to be in contact with the twelfth portion, the one end of the fifteenth portion being coupled to the other end of the fourteenth portion;
a sixteenth portion having one end and other end, extending in the first direction, and provided at a position different from a position of the twelfth portion, the one end of the sixteenth portion being electrically coupled to the other end of the fifteenth portion;
a seventeenth portion having one end and other end and extending in the second direction in parallel with the twelfth portion, the one end of the seventeenth portion being electrically coupled to the other end of the sixteenth portion;
an eighteenth portion having one end and other end and extending in the first direction in parallel with the thirteenth portion, the one end of the eighteenth portion being coupled to the other end of the seventeenth portion;
a nineteenth portion having one end and other end, extending in the second direction in parallel with the fourteenth portion, and provided so as not to be in contact with the eleventh portion, the one end of the nineteenth portion being coupled to the other end of the eighteenth portion; and
a twentieth portion having one end and other end, extending in the first direction in parallel with the eleventh portion, and provided so as not to be in contact with the fourteenth portion, the one end of the twentieth portion being coupled to the other end of the nineteenth portion.

6. The semiconductor circuit according to claim 5, wherein
a part of the twelfth portion is provided above a part of the second portion,
a part of the fourteenth portion is provided above a part of the fourth portion,
a part of the seventeenth portion is provided above a part of the seventh portion, and
a part of the nineteenth portion is provided above a part of the ninth portion.

7. The semiconductor circuit according to claim 5, wherein
the first portion, the fifth portion, the thirteenth portion, and the eighteenth portion are arranged side by side in the second direction, and
the third portion, the eighth portion, the eleventh portion, and the fifteenth portion are arranged side by side in the second direction.

8. The semiconductor circuit according to claim 1, wherein
the surface of the semiconductor substrate is parallel to a plane defined by a first direction and a second direction that intersects the first direction,
a third direction is included in the plane defined by the first direction and the second direction and is different from the first direction and the second direction,
a fourth direction is included in the plane defined by the first direction and the second direction and is different from the first direction, the second direction, and the third direction, and
the first T-coil includes:
a first portion having one end and other end and extending in the first direction;
a second portion having one end and other end and extending in the third direction, the one end of the second portion being coupled to the other end of the first portion;
a third portion having one end and other end and extending in the second direction, the one end of the third portion being coupled to the other end of the second portion;
a fourth portion having one end and other end and extending in the fourth direction, the one end of the fourth portion being coupled to the other end of the third portion;
a fifth portion having one end and other end and extending in the first direction, the one end of the fifth portion being coupled to the other end of the fourth portion;
a sixth portion having one end and other end and extending in the third direction, the one end of the sixth portion being coupled to the other end of the fifth portion;
a seventh portion having one end and other end and extending in the second direction, the one end of the seventh portion being coupled to the other end of the sixth portion;
an eighth portion having one end and other end, extending in the fourth direction, and provided so as not to be in contact with the first portion, the one end of the eighth portion being coupled to the other end of the seventh portion;
a ninth portion having one end and other end, extending in the first direction in parallel with the first portion, and provided so as to be in contact with neither the second portion nor the third portion, the one end of the ninth portion being coupled to the other end of the eighth portion;
a tenth portion having one end and other end, extending in the first direction, and provided at a position different from a position of the second portion and a position of the third portion, the one end of the tenth portion being electrically coupled to the other end of the ninth portion;
an eleventh portion having one end and other end and extending in the second direction in parallel with the third portion, the one end of the eleventh portion being electrically coupled to the other end of the tenth portion;
a twelfth portion having one end and other end and extending in the fourth direction in parallel with the fourth portion, the one end of the twelfth portion being coupled to the other end of the eleventh portion;
a thirteenth portion having one end and other end extending in the first direction in parallel with the fifth portion, the one end of the thirteenth portion being coupled to the other end of the twelfth portion;
a fourteenth portion having one end and other end extending in the third direction in parallel with the sixth portion, the one end of the fourteenth portion being coupled to the other end of the thirteenth portion;
a fifteenth portion having one end and other end, extending in the second direction in parallel with the seventh portion, and provided so as not to be in contact with the first portion, the one end of the fifteenth portion being coupled to the other end of the fourteenth portion; and
a sixteenth portion having one end and other end, extending in the first direction in parallel with the first portion, and provided so as not to be in contact with the eighth portion, the one end of the sixteenth portion being coupled to the other end of the fifteenth portion.

9. The semiconductor circuit according to claim 8, wherein the second T-coil includes:
a seventeenth portion having one end and other end and extending in the first direction;
an eighteenth portion having one end and other end and extending in the fourth direction, the one end of the eighteenth portion being coupled to the other end of the seventeenth portion;
a nineteenth portion having one end and other end and extending in the second direction, the one end of the nineteenth portion being coupled to the other end of the eighteenth portion;
a twentieth portion having one end and other end and extending in the third direction, the one end of the twentieth portion being coupled to the other end of the nineteenth portion;
a twenty-first portion having one end and other end and extending in the first direction, the one end of the twenty-first portion being coupled to the other end of the twentieth portion;
a twenty-second portion having one end and other end and extending in the fourth direction, the one end of the twenty-second portion being coupled to the other end of the twenty-first portion;
a twenty-third portion having one end and other end and extending in the second direction, the one end of the twenty-third portion being coupled to the other end of the twenty-second portion;
a twenty-fourth portion having one end and other end, extending in the third direction, and provided so as not to be in contact with the seventeenth portion, the one end of the twenty-fourth portion being coupled to the other end of the twenty-third portion;
a twenty-fifth portion having one end and other end, extending in the first direction in parallel with the seventeenth portion, and provided so as to be in contact with neither the eighteenth portion nor the nineteenth portion, the one end of the twenty-fifth portion being coupled to the other end of the twenty-fourth portion;
a twenty-sixth portion having one end and other end, extending in the first direction, and provided at a position different from a position of the eighteenth portion and a position of the nineteenth portion, the one end of the twenty-sixth portion being electrically coupled to the other end of the twenty-fifth portion;
a twenty-seventh portion having one end and other end and extending in the second direction in parallel with the nineteenth portion, the one end of the twenty-seventh portion being electrically coupled to the other end of the twenty-sixth portion;
a twenty-eighth portion having one end and other end and extending in the third direction in parallel with the twentieth portion, the one end of the twenty-eighth portion being coupled to the other end of the twenty-seventh portion;
a twenty-ninth portion having one end and other end and extending in the first direction in parallel with the twenty-first portion, the one end of the twenty-ninth portion being coupled to the other end of the twenty-eighth portion;
a thirtieth portion having one end and other end and extending in the fourth direction in parallel with the twenty-second portion, the one end of the thirtieth portion being coupled to the other end of the twenty-ninth portion;
a thirty-first portion having one end and other end, extending in the second direction in parallel with the twenty-third portion, and provided so as not to be in contact with the seventeenth portion, the one end of the thirty-first portion being coupled to the other end of the thirtieth portion; and
a thirty-second portion having one end and other end, extending in the first direction in parallel with the seventeenth portion, and provided so as not to be in contact with the twenty-fourth portion, the one end of the thirty-second portion being coupled to the other end of the thirty-first portion.

10. The semiconductor circuit according to claim 9, wherein
a part of the nineteenth portion is provided above a part of the third portion,
a part of the twenty-third portion is provided above a part of the seventh portion,
a part of the twenty-seventh portion is provided above a part of the twelfth portion, and
a part of the thirty-first portion is provided above a part of the sixteenth portion.

11. The semiconductor circuit according to claim 9, wherein
the first portion, the ninth portion, the twenty-first portion, and the twenty-ninth portion are arranged side by side in the second direction, and
the fifth portion, the fourteenth portion, the seventeenth portion, and the twenty-fifth portion are arranged side by side in the second direction.

12. A memory system comprising:
a memory device; and
a memory controller including an interface circuit including a semiconductor circuit and configured to control operation of the memory device based on communication via the interface circuit, wherein
the semiconductor circuit includes:
a semiconductor substrate;
a first T-coil provided apart from the semiconductor substrate and including a first inductive element and a second inductive element which are coupled in series; and
a second T-coil provided apart from the semiconductor substrate and including a third inductive element and a fourth inductive element which are coupled in series,
a part of the first T-coil is provided at a first position in a vertical direction from a surface of the semiconductor substrate,
a part of the second T-coil is provided at a second position in the vertical direction from the surface to overlap with the part of the first T-coil in the vertical direction,
in the vertical direction, a first distance from the semiconductor substrate to the first position is different from a second distance from the semiconductor substrate to the second position,
the first T-coil is configured to receive a first signal having a first polarity of a differential signal, and
the second T-coil is configured to receive a second signal having a second polarity different from the first polarity of the differential signal.

13. The memory system according to claim 12, wherein each of the first T coil and the second T coil has one of a square annular shape and an octagonal annular shape.

14. The memory system according to claim 12, wherein a direction of a current of the first signal flowing through the first T-coil and a direction of a current of the second signal flowing through the second T-coil are aligned in an area where the part of the first T-coil and the part of the second T-coil overlap with each other in the vertical direction.

15. The memory system according to claim 12, wherein
the surface of the semiconductor substrate is parallel to a plane defined by a first direction and a second direction that intersects the first direction, and
the first T-coil includes:
a first portion having one end and other end and extending in the first direction;
a second portion having one end and other end and extending in the second direction, the one end of the second portion being coupled to the other end of the first portion;
a third portion having one end and other end and extending in the first direction, the one end of the third portion being coupled to the other end of the second portion;
a fourth portion having one end and other end, extending in the second direction, and provided so as not to be in contact with the first portion, the one end of the fourth portion being coupled to the other end of the third portion;
a fifth portion having one end and other end, extending in the first direction in parallel with the first portion, and provided so as not to be in contact with the second portion, the one end of the fifth portion being coupled to the other end of the fourth portion;
a sixth portion having one end and other end, extending in the first direction, and provided at a position different from a position of the second portion, the one end of the sixth portion being electrically coupled to the other end of the fifth portion;
a seventh portion having one end and other end and extending in the second direction in parallel with the second portion, the one end of the seventh portion being electrically coupled to the other end of the sixth portion;
an eighth portion having one end and other end and extending in the first direction in parallel with the third portion, the one end of the eighth portion being coupled to the other end of the seventh portion;
a ninth portion having one end and other end, extending in the second direction in parallel with the fourth portion, and provided so as not to be in contact with the first portion, the one end of the ninth portion being coupled to the other end of the eighth portion; and
a tenth portion having one end and other end, extending in the first direction in parallel with the first portion, and provided so as not to be in contact with the fourth portion, the one end of the tenth portion being coupled to the other end of the ninth portion.

16. The memory system according to claim 12, wherein
the surface of the semiconductor substrate is parallel to a plane defined by a first direction and a second direction that intersects the first direction,
a third direction is included in the plane defined by the first direction and the second direction and is different from the first direction and the second direction,
a fourth direction is included in the plane defined by the first direction and the second direction and is different from the first direction, the second direction, and the third direction, and
the first T-coil includes:
a first portion having one end and other end and extending in the first direction;
a second portion having one end and other end and extending in the third direction, the one end of the second portion being coupled to the other end of the first portion;
a third portion having one end and other end and extending in the second direction, the one end of the third portion being coupled to the other end of the second portion;
a fourth portion having one end and other end and extending in the fourth direction, the one end of the fourth portion being coupled to the other end of the third portion;
a fifth portion having one end and other end and extending in the first direction, the one end of the fifth portion being coupled to the other end of the fourth portion;
a sixth portion having one end and other end and extending in the third direction, the one end of the sixth portion being coupled to the other end of the fifth portion;
a seventh portion having one end and other end and extending in the second direction, the one end of the seventh portion being coupled to the other end of the sixth portion;
an eighth portion having one end and other end, extending in the fourth direction, and provided so as not to be in contact with the first portion, the one end of the eighth portion being coupled to the other end of the seventh portion;
a ninth portion having one end and other end, extending in the first direction in parallel with the first portion, and provided so as to be in contact with neither the second portion nor the third portion, the one end of the ninth portion being coupled to the other end of the eighth portion;
a tenth portion having one end and other end, extending in the first direction, and provided at a position different from a position of the second portion and a position of the third portion, the one end of the tenth portion being electrically coupled to the other end of the ninth portion;
an eleventh portion having one end and other end and extending in the second direction in parallel with the third portion, the one end of the eleventh portion being electrically coupled to the other end of the tenth portion;
a twelfth portion having one end and other end and extending in the fourth direction in parallel with the fourth portion, the one end of the twelfth portion being coupled to the other end of the eleventh portion;
a thirteenth portion having one end and other end extending in the first direction in parallel with the fifth portion, the one end of the thirteenth portion being coupled to the other end of the twelfth portion;
a fourteenth portion having one end and other end extending in the third direction in parallel with the sixth portion, the one end of the fourteenth portion being coupled to the other end of the thirteenth portion;
a fifteenth portion having one end and other end, extending in the second direction in parallel with the seventh portion, and provided so as not to be in contact with the first portion, the one end of the fifteenth portion being coupled to the other end of the fourteenth portion; and
a sixteenth portion having one end and other end, extending in the first direction in parallel with the first portion, and provided so as not to be in contact with the eighth portion, the one end of the sixteenth portion being coupled to the other end of the fifteenth portion.

17. An information processing device comprising:
an interface circuit including a semiconductor circuit; and
a processor configured to control an external device coupled thereto via the interface circuit,
wherein the semiconductor circuit includes:
a semiconductor substrate;
a first T-coil provided apart from the semiconductor substrate and including a first inductive element and a second inductive element which are coupled in series; and
a second T-coil provided apart from the semiconductor substrate and including a third inductive element and a fourth inductive element which are coupled in series,
a part of the first T-coil is provided at a first position in a vertical direction from a surface of the semiconductor substrate,
a part of the second T-coil is provided at a second position in the vertical direction from the surface to overlap with the first T-coil in the vertical direction,
in the vertical direction, a first distance from the semiconductor substrate to the first position is different from a second distance from the semiconductor substrate to the second position;
the first T-coil is configured to receive a first signal having a first polarity of a differential signal; and
the second T-coil is configured to receive a second signal having a second polarity different from the first polarity of the differential signal.

18. The information processing device according to claim 17, wherein each of the first T-coil and the second T-coil has one of a square annular shape and an octagonal annular shape.

19. The information processing device according to claim 17, wherein
the surface of the semiconductor substrate is parallel to a plane defined by a first direction and a second direction that intersects the first direction, and
the first T-coil includes:
a first portion having one end and other end and extending in the first direction;
a second portion having one end and other end and extending in the second direction, the one end of the second portion being coupled to the other end of the first portion;
a third portion having one end and other end and extending in the first direction, the one end of the third portion being coupled to the other end of the second portion;
a fourth portion having one end and other end, extending in the second direction, and provided so as not to be in contact with the first portion, the one end of the fourth portion being coupled to the other end of the third portion;
a fifth portion having one end and other end, extending in the first direction in parallel with the first portion, and provided so as not to be in contact with the second portion, the one end of the fifth portion being coupled to the other end of the fourth portion;
a sixth portion having one end and other end, extending in the first direction, and provided at a position different from a position of the second portion, the one end of the sixth portion being electrically coupled to the other end of the fifth portion;
a seventh portion having one end and other end and extending in the second direction in parallel with the second portion, the one end of the seventh portion being electrically coupled to the other end of the sixth portion;
an eighth portion having one end and other end and extending in the first direction in parallel with the third portion, the one end of the eighth portion being coupled to the other end of the seventh portion;
a ninth portion having one end and other end, extending in the second direction in parallel with the fourth portion, and provided so as not to be in contact with the first portion, the one end of the ninth portion being coupled to the other end of the eighth portion;
a tenth portion having one end and other end, extending in the first direction in parallel with the first portion, and provided so as not to be in contact with the fourth portion, the one end of the tenth portion being coupled to the other end of the ninth portion.

20. The information processing device according to claim 17, wherein
the surface of the semiconductor substrate is parallel to a plane defined by a first direction and a second direction that intersects the first direction,
a third direction is included in the plane defined by the first direction and the second direction and is different from the first direction and the second direction,
a fourth direction is included in the plane defined by the first direction and the second direction and is different from the first direction, the second direction, and the third direction, and
the first T-coil includes:
a first portion having one end and other end and extending in the first direction;
a second portion having one end and other end and extending in the third direction, the one end of the second portion being coupled to the other end of the first portion;
a third portion having one end and other end and extending in the second direction, the one end of the third portion being coupled to the other end of the second portion;
a fourth portion having one end and other end and extending in the fourth direction, the one end of the fourth portion being coupled to the other end of the third portion;
a fifth portion having one end and other end and extending in the first direction, the one end of the fifth portion being coupled to the other end of the fourth portion;
a sixth portion having one end and other end and extending in the third direction, the one end of the sixth portion being coupled to the other end of the fifth portion;
a seventh portion having one end and other end and extending in the second direction, the one end of the seventh portion being coupled to the other end of the sixth portion;
an eighth portion having one end and other end, extending in the fourth direction, and provided so as not to be in contact with the first portion, the one end of the eighth portion being coupled to the other end of the seventh portion;
a ninth portion having one end and other end, extending in the first direction in parallel with the first portion, and provided so as to be in contact with neither the second portion nor the third portion, the one end of the ninth portion being coupled to the other end of the eighth portion;
a tenth portion having one end and other end, extending in the first direction, and provided at a position different from a position of the second portion and a position of the third portion, the one end of the tenth portion being electrically coupled to the other end of the ninth portion;
an eleventh portion having one end and other end and extending in the second direction in parallel with the third portion, the one end of the eleventh portion being electrically coupled to the other end of the tenth portion;
a twelfth portion having one end and other end and extending in the fourth direction in parallel with the fourth portion, the one end of the twelfth portion being coupled to the other end of the eleventh portion;
a thirteenth portion having one end and other end extending in the first direction in parallel with the fifth portion, the one end of the thirteenth portion being coupled to the other end of the twelfth portion;
a fourteenth portion having one end and other end extending in the third direction in parallel with the sixth portion, the one end of the fourteenth portion being coupled to the other end of the thirteenth portion;
a fifteenth portion having one end and other end, extending in the second direction in parallel with the seventh portion, and provided so as not to be in contact with the first portion, the one end of the fifteenth portion being coupled to the other end of the fourteenth portion; and
a sixteenth portion having one end and other end, extending in the first direction in parallel with the first portion, and provided so as not to be in contact with the eighth portion, the one end of the sixteenth portion being coupled to the other end of the fifteenth portion.
